(19) United States
(12) Patent Application Publication
(10) Pub. No.: US 2015/0069626 A1
(43) Pub. Date: Mar. 12, 2015

(54) CHIP PACKAGE, CHIP PACKAGE MODULE BASED ON THE CHIP PACKAGE, AND METHOD OF MANUFACTURING THE CHIP PACKAGE

(71) Applicant: LINGSEN PRECISION INDUSTRIES, LTD., Taichung City (TW)

(72) Inventor: Wei-Jen CHEN, Taichung City (TW)

(73) Assignee: LINGSEN PRECISION INDUSTRIES, LTD., Taichung City (TW)

(21) Appl. No.: 14/066,179

(22) Filed: Oct. 29, 2013

(30) Foreign Application Priority Data
Sep. 10, 2013 (TW) 102132667

(51) Int. Cl. H01L 23/373; H01L 21/56

(52) U.S. Cl. CPC H01L 23/3736; H01L 21/561
USPC 257/774; 438/118

(57) ABSTRACT

A chip package is formed of a complex substrate and a chip. The complex substrate includes a core plate, a thermally-conductive insulated layer, and a through hole running through the core plate and the thermally-conductive insulated layer. The core plate is fixed to the core plate and buried into the thermally-conductive insulated layer. An upper electrode of the chip is connected with a first circuit layer. The first circuit layer is disposed on a top side of the thermally-conductive insulated layer, into the through hole, and on a lower surface of the core plate. A lower electrode of the chip is connected with a second circuit layer. The second circuit layer is disposed on the lower surface of the core plate. In light of the structure, the chip package has a simplified manufacturing process and reduces the production cost and the package size.

### BACKGROUND OF THE INVENTION

1. Field of the Invention

The present invention relates generally to the chip packaging technology and more particularly, to a chip package, a chip package module based on the chip package, and a method of manufacturing the chip package.

2. Description of the Related Art

A conventional process of manufacturing light emitting diode (LED) package includes the steps of fastening LED chips to a substrate, next making multiple wires, e.g. golden wires, connected between the LED chips and the substrate by wire bonding, and finally packaging the LED chips via an encapsulating member, e.g. epoxy resin. However, such package fails to effectively reduce its thickness as a whole due to the requirement for circuit conduction of the LED chips and connection of the wires to further result in insufficient competitivity while applied to products.

To solve the problem of the aforesaid package, Taiwan Patent Laid-open No. 201013858 disclosed that the LED chips are mounted inside the substrates, one of which is superposed on the other, and a single-sided or double-sided redistribution layer (RDL) is available, thus reducing the thickness of the whole package. However, the manufacturing process of this package is quite complicated and the effect of thickness reduction is actually limited, so it fails to indeed decrease the production cost and the thickness of the package.

### SUMMARY OF THE INVENTION

The first objective of the present invention is to provide a chip package which can reduce production cost and package thickness.

The foregoing objective of the present invention is attained by the chip package formed of a complex substrate, a chip, an encapsulating layer, a first circuit layer, and a second circuit layer. The complex substrate includes a core plate, a thermally-conductive insulated layer, and a through hole running through the core plate and the thermally-conductive insulated layer. The core plate includes an upper surface, a lower surface opposite to the upper surface, and a lower opening formed on the lower surface. The thermally-conductive insulated layer is formed on the upper surface of the core plate and includes a top side and an upper opening formed on the top side. The upper opening is opposite to the lower opening. The chip is mounted inside the thermally-conductive insulated layer and includes an upper electrode and a lower electrode. The upper electrode corresponds to the lower opening. The lower electrode is fixed to the upper surface and corresponds to the lower opening. The encapsulating layer partially encapsulates the chip to expose the upper electrode of the chip. The first circuit layer is disposed on the top side of the thermally-conductive insulated layer, into the through hole, and on the lower surface of the core plate, being electrically connected with the upper electrode via the upper opening. The second circuit layer is disposed on the lower surface of the core plate and electrically connected with the lower electrode of the chip via the lower opening.

The second objective of the present invention is to provide a chip package module which is formed of at least two of the aforesaid chip packages interconnected together and a cutting way located between the at least two chip packages for a cutter to cut along to further separate the two chip packages from each other.

The third objective of the present invention is to provide a method of manufacturing the aforesaid chip packages includes the steps of fastening an lower electrode of a chip to an upper electrically-conductive layer of a core plate; making an encapsulating layer encapsulate the chip; pressing a thermally-conductive insulated layer to an upper surface of the core plate to make the chip buried into the thermally-conductive insulated layer; processing a top side of the thermally-conductive insulated layer and a top side of the encapsulating layer to make an upper opening running therethrough for exposing an upper electrode of the chip via the upper opening and processing a lower surface of the core plate to make a lower opening running therethrough to expose the upper electrically-conductive layer from the lower opening; and electroplating an electrically-conductive material to the top side of the thermally-conductive layer, into the through hole, and to the lower surface of the core plate, making the electrically-conductive material patterned to form a first circuit layer and a second circuit layer, and finally making the first and second circuit layers electrically connected with the upper electrode of the chip and the upper electrically-conductive layer of the core plate.

### BRIEF DESCRIPTION OF THE DRAWINGS

FIG. 1 is a structural view of the chip package module of the present invention.

FIG. 2 is a structural view of the chip package of the present invention.

FIGS. 3a and 3b are a flow chart of the method of the present invention.

### DETAILED DESCRIPTION OF PREFERRED EMBODIMENTS

Structural features and desired effects of the present invention will become more fully understood by reference to a preferred embodiment given hereunder. However, it is to be understood that the embodiment is given by way of illustration only, thus is not limitative of the claim scope of the present invention.

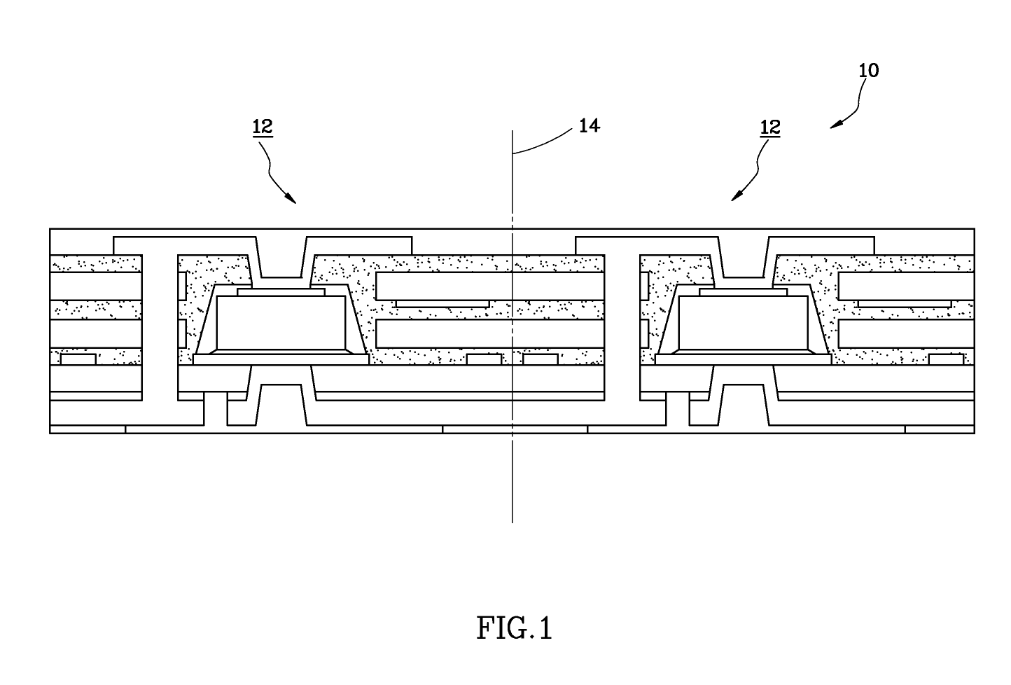

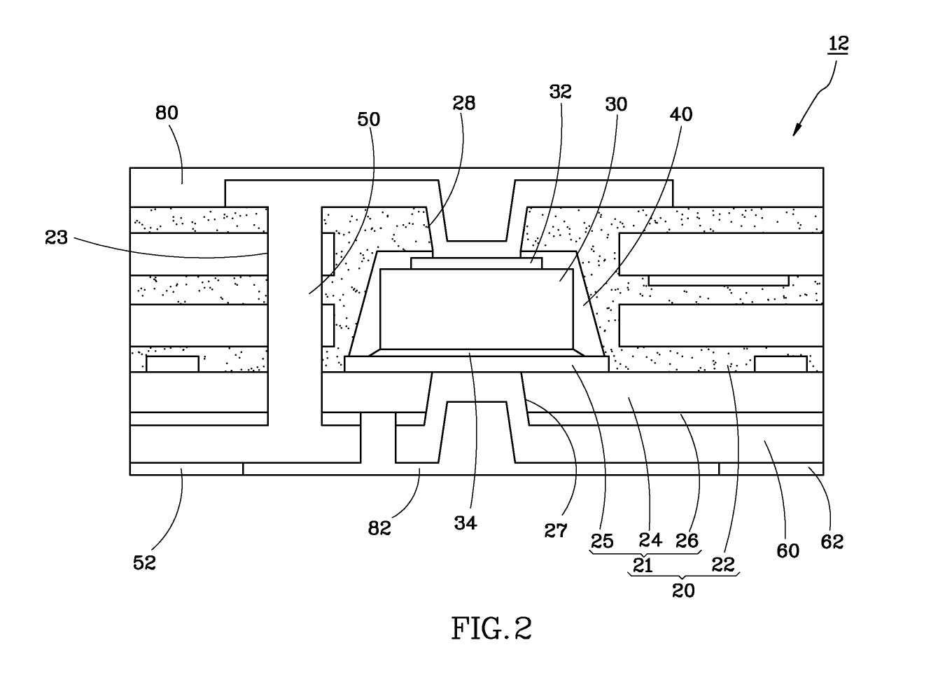

Referring to FIG. 1, a chip package module 10 is formed of a plurality of chip packages 12 interconnected together. A cutting way 14 is formed between every two adjacent chip packages 12 for a cutter (not shown) to cut the chip package module 12 into separate chip packages 12. Referring to FIG. 2, the chip package 12 is formed of a complex substrate 20, a chip 30, an encapsulating layer 40, a first circuit layer 50, and a second circuit layer 60. The detailed descriptions and operations of these elements as well as their interrelations are recited in the respective paragraphs as follows.

The complex substrate 20 includes a core plate 21, a thermally-insulated layer 22, and a through hole 23 running through the core plate 21 and the thermally-conductive layer 22. The core plate 21 includes an insulative layer 24, an upper electrically-conductive layer 25, and a lower electrically-conductive layer 26. The upper and lower electrically-conductive layers 25 and 26 are mounted to an upper surface and a lower surface of the insulative layer 24, respectively. The core plate 21 further includes a lower opening 27 running through the lower electrically-conductive layer 26 and the insulative layer 24 to expose the upper electrically-conductive layer 25. The thermally-conductive layer 22 is mounted to the upper surface of the core plate 21 and includes an upper opening 28 formed on a top side thereof and opposite to the lower opening 27 of the core plate 21. In addition, the thermally-conductive layer 22 can be made of a self-adhesive copper foil or a soft ceramic thermally-conductive adhesive film, the former of which is preferable in this embodiment.

The chip 30, which is an LED chip as an example, is buried into the thermally-conductive insulated layer 22 and includes an upper electrode 32, which is anode, and a lower electrode 34, which is cathode. The upper electrode 32 of the chip 30 corresponds to the upper opening 28 of the thermally-conductive insulated layer 22. The lower electrode 34 of the chip 30 is fixed to the upper electrically-conductive layer 25 of the core plate 21 and corresponds to the lower opening 27.

The encapsulating layer 40 partially encapsulates the chip 30 to expose the upper electrode 32 to prevent the chip 30 from erosion or ablation.

The first circuit layer 50 is disposed on the top side of the thermally-conductive insulated layer 22, into the through hole 23, and to the lower surface of the core plate 21 and electrically connected with the upper opening 28 and the upper electrode 32.

The second circuit layer 60 is disposed on the lower surface of the core plate 21 and electrically connected with the upper electrically-conductive layer 25 via the lower opening 27 to make the second circuit layer 60 and the lower electrode 34 electrically connected via the upper electrically-conductive layer 25.

In addition, the chip package 12 of the present invention further includes a first solder mask layer 80 and a second solder mask layer 82. The first solder mask layer 80 is disposed on the top side of the thermally-conductive layer 22 and covers the first circuit layer 50 for providing the first circuit layer 50 with protection of insulation.

When a first contact 52 of the first circuit layer 50 and a second contact 62 of the second circuit layer 60 are charged with positive voltage, the current flows from the first circuit layer 50 to the upper electrode 32 of the chip 30 and after flowing through the chip 30, it flows from the lower electrode 34 of the chip 30 to the second circuit layer 60 to make the chip 30 emit rays.

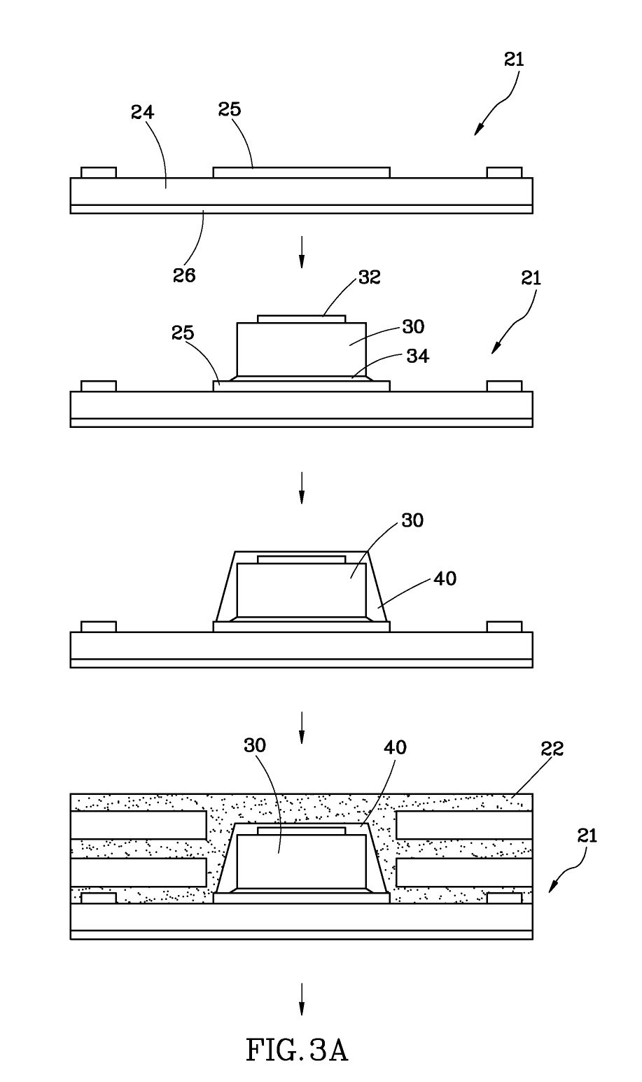

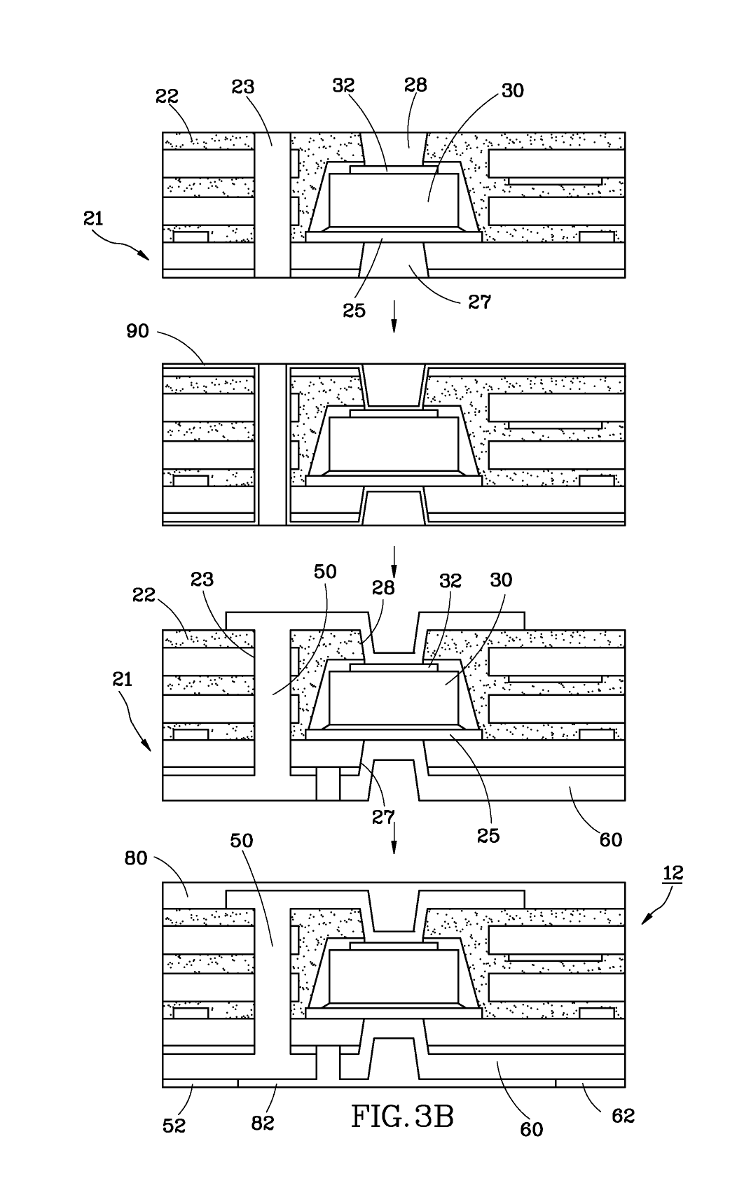

Referring to FIG. 3A and FIG. 3B, a method of manufacturing the chip package 12 includes the following steps.

A) Fasten a lower electrode 34 of a chip 30 to an upper electrically-conductive layer 25 of a core plate 21. In this step, there are two ways of fastening the lower electrode 34 to the upper electrically-conductive layer 25. One of the two ways is to apply soldering flux to the chip 30 and then mount the chip 30 to the upper electrically-conductive layer 25 by hot-pressing tin soldering. The other way is to coat a solder onto the upper electrically-conductive layer 25 of the core plate 21 and then mount the chip 30 to the upper electrically-conductive layer 25 for reflow process to fasten the lower electrode 34 to the upper electrically-conductive layer 25.

B) Prepare and make an encapsulating layer 40 cover the chip 30 and then apply black oxide finish to the chip 30 and the encapsulating layer 40. The encapsulating layer 40 can prevent the chip 30 from damage resulting from erosion in the process of the black oxide finish.

C) Press the thermally-conductive insulated layer 22 to an upper surface of the core plate 21 to bury the chip 30 into the thermally-conductive insulated layer 22. The encapsulating layer 40 can prevent the chip 30 from ablation in the process of pressing the thermally-conductive insulated layer 22.

D) Process the thermally-conductive insulated layer 22 and the core plate 21 by means of carbon dioxide laser to make a through hole 23 and then process a top side of the thermally-conductive insulated layer 22 and a top side of the encapsulating layer 40 to make an upper opening 28 to further expose the upper electrode 32 from the upper opening 28. Next, process a lower surface of the core plate 21 to make a lower opening 27 to expose the upper electrically-conductive layer 25 from the lower opening 27.

E) Proceed to a desmear process based on plasma after laser drilling. Next, electroplate an electrically-conductive material, which is copper preferably, to the top side of the thermally-conductive insulated layer 22, into the through hole 23, and to the lower surface of the core plate 21. Next, make the electrically-conductive material patterned to form a first circuit layer 50 and a second circuit layer 60 and then make the first circuit layer 50 electrically connected with the upper electrode 32 of the chip 30 via the upper opening 28 and make the second circuit layer 60 electrically connected with the upper electrically-conductive layer 25 of the core 21 via the lower opening 27. After the first and second circuit layers 50 and 60 are disposed, dispose a first solder mask layer 80 to the top side of the thermally-conductive insulated layer 22 to cover the first circuit layer 50, then dispose a second solder mask layer 82 to the lower surface of the core plate 21 to cover the first and second circuit layers 50 and 60, and finally form two chemical gold layers on the first and second circuit layers 50 and 60, respectively. The two chemical gold layers can serve as a first contact 52 and a second contact 62. In this way, the chip package 12 of the present invention can be completed in light of the aforesaid steps.

In conclusion, the present invention can complete the manufacturing process of the chip package 12 of the chip 30 only based on the complex substrate 20 formed of the single core plate 21 and the thermally-conductive insulated layer 22 and compared with the conventional wire-bonding process or the prior art, which is based on the layout of two substrates superposed on each other and the RDL, the chip package 12 of the present invention not only has the simplified manufacturing process but effectively reduces the production cost and the package size.

What is claimed is:

1. A chip package comprising:
a complex substrate having a core plate, a thermally-conductive insulated layer, and a through hole running through the core plate the thermally-conductive insulated layer, the core plate having an upper surface, a lower surface opposite to the upper surface, and a lower opening formed on the lower surface, the thermally-conductive insulated layer formed on the upper surface of the core plate and having a top side, the thermally-conductive insulated layer having an upper opening formed on the top side of the thermally-conductive insulated layer, the upper opening being opposite to the lower opening of the core plate;
a chip buried inside the thermally-conductive layer and having an upper electrode and a lower electrode, the upper electrode corresponding to the upper opening, the lower electrode being fixed to the upper surface and corresponding to the lower opening;
an encapsulating layer partially encapsulating the chip and exposing the upper electrode;
a first circuit layer disposed to the top side of the thermally-conductive insulated layer, into the through hole, and to the lower surfac of the core plate, the first circuit layer being electrically connected with the upper electrode via the lower opening; and
a second circuit layer disposed to the lower surface of the core plate and electrically connected with the lower electrode of the chip via the lower opening of the pore plate.

2. The chip package as defined in claim 1, wherein the core plate comprises an insulative layer, an upper electrically-conductive layer, and a lower electrically-conductive layer, the upper and lower electrically-conductive layers being disposed to the upper and lower surfaces of the insulative layer, the lower opening running through the lower electrically-conductive layer and the insulative layer to expose the upper electrically-conductive layer, the lower electrode being fixed to the upper electrically-conductive layer and electrically connected with the second circuit layer.

3. The chip package as defined in claim 1, wherein the thermally-conductive layer comprises a first solder mask layer formed on the top side thereof and covering the first circuit layer; the core plate comprises a second solder mask layer formed on the lower surface thereof and covering the first and second circuit layers.

4. The chip package as defined in claim 1, wherein the first circuit layer the first circuit layer comprises a first contact formed on the lower surface of the core plate, and the second circuit layer comprises a second contact formed on the lower surface of the core plate.

5. The chip package as defined in claim 1, wherein the thermally-conductive layer is a self-adhesive copper foil.

6. The chip package as defined in claim 1, wherein the thermally-conductive layer is a soft ceramic thermally-conductive adhesive film.

7. A chip package module comprising at least two chip packages defined in claim 1, wherein the at least two chip packages are interconnected together and a cutting way is formed between the two chip packages

8. The chip package as defined in claim 7, wherein the core plate comprises an insulative layer, an upper electrically-conductive layer, and a lower electrically-conductive layer, the upper and lower electrically-conductive layers being disposed on the upper and lower surfaces of the insulative layer, respectively, the lower opening running through the lower electrically-conductive layer and the insulative layer to expose the upper electrically-conductive layer, the lower electrode of the chip being fixed to the upper electrically-conductive layer and electrically connected with the second circuit layer.

9. The chip package as defined in claim 7, wherein the thermally-conductive insulated layer comprises a first solder mask layer formed on the top side thereof and covering the first circuit layer; the core plate comprises a second solder mask layer formed on the lower surface thereof and covering the first and second circuit layers.

10. The chip package as defined in claim 7, wherein the first circuit layer comprises a first contact formed on the lower surface of the core plate and the second circuit layer comprises a second contact formed on the lower surface of the core plate.

11. The chip package as defined in claim 7, wherein the the thermally-conductive layer is a self-adhesive copper foil.

12. The chip package as defined in claim 7, wherein the thermally-conductive layer is a soft ceramic thermally-conductive adhesive film.

13. A method of manufacturing a chip package comprises steps of:
A) fastening a lower electrode of a chip to an upper electrically-conductive layer of a core plate;
B) making an encapsulating layer cover the chip;
C) pressing a thermally-conductive insulated layer to the core plate to bury the chip into the thermally-conductive insulated layer;
D) processing the thermally-conductive insulated layer and the core plate to make a through hole, processing a top side of the thermally-conductive insulated layer and a top side of the encapsulating layer to make an upper opening to expose the upper electrode of the chip from the upper opening, and processing a lower surface of the core plate to make a lower opening to expose the upper electrically-conductive layer of the core plate from the lower opening; and
E) electroplating an electrically-conductive material to the top side of the thermally-conductive layer, into the through hole, and to the lower surface of the core plate, making the electrically-conductive material patterned to form a first circuit layer and a second circuit layer, and making the first circuit layer electrically connected with the upper electrode of the chip and making the second circuit layer electrically connected with the upper electrically-conductive layer.

14. The method as defined in claim 13, wherein in the step A), the lower electrode of the chip is fastened to the upper electrically-conductive layer of the core plate by hot pressing based on soldering flux applied to the chip.

15. The method as defined in claim 13, wherein in the step A), the lower electrode of the chip is fastened to the upper electrically-conductive layer of the core plate by a reflow process based on a solder coated to the upper electrically-conductive layer of the core plate.

16. The method as defined in claim 13, wherein in the step B), after the encapsulating layer covers the chip, proceed with black oxide finish.

17. The method as defined in claim 13, wherein in the step D), the through hole, the upper opening, and the lower opening are formed by laser processing.

18. The method as defined in claim 17, wherein in the step E), before the electrically-conductive material is electroplated, proceed to a desmear process based on plasma after laser drilling.

19. The method as defined in claim 13, wherein in the step E), after the electrically-conductive material is patterned, dispose a first solder mask layer to the top side of the thermally-conductive insulated layer to make the first solder mask layer cover the first circuit layer and meanwhile dispose a second solder mask layer to the lower surface of the core plate to cover the first and second circuit layers.

20. The method as defined in claim 19, wherein in the step E), after the first and second solder mask layers are disposed, form two chemical gold layers on the first and second circuit layers, respectively, and make the two chemical gold layers serve as a first contact and a second contact.

21. The method as defined in claim 13, wherein the thermally-conductive layer is a self-adhesive copper foil.

22. The method as defined in claim 13, wherein the thermally-conductive layer is a soft ceramic thermally-conductive adhesive film.
